(19) United States
(12) Patent Application Publication
(10) Pub. No.: US 2013/0088817 A1
(43) Pub. Date: Apr. 11, 2013

(54) FIXING MECHANISM AND ELECTRONIC DEVICE USING THE SAME

(71) Applicants: YUAN-MING WANG, Shenzhen City (CN); XUE-FENG WAN, Shenzhen City (CN); BAO-GANG ZHAO, Shenzhen City (CN); PING LI, Shenzhen City (CN)

(72) Inventors: YUAN-MING WANG, Shenzhen City (CN); XUE-FENG WAN, Shenzhen City (CN); BAO-GANG ZHAO, Shenzhen City (CN); PING LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/563,846

(22) Filed: Aug. 1, 2012

(30) Foreign Application Priority Data
Oct. 11, 2011 (CN) 201120383747.1

(51) Int. Cl. H05K 5/03

(52) U.S. Cl. 361/679.01

(57) ABSTRACT

A housing of an electronic device includes a lower cover, a front panel and a fixing mechanism for securing the front panel to the lower cover. The fixing mechanism is arranged between the lower cover and the front panel. The fixing mechanism includes a fixing arm and a protrusion protruding from the lower cover. The fixing arm is located on the front panel and defines a latching hole. The protrusion is capable of latching in the latching hole for preventing the front panel from disengaging with the lower cover in a first direction parallel to the fixing arm. A fixing mechanism used in a housing of an electronic device is also provided.

### BACKGROUND

1. Technical Field

The present disclosure relates to electronic devices; and particularly, to an electronic device having a fixing mechanism.

2. Description of Related Art

Housings of electronic devices, such as DVD players, include a lower cover, a front panel and a back panel arranged on opposite ends of the lower cover, and an upper cover. The upper cover, the lower cover, the front and back panels are successively connected to form a closed space to protect components of the electronic device. The front panel is typically assembled and fixed to the lower cover by mean of screws, and tools are required for disassembly and assembly of the back panel, this is inconvenience and time consuming.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partially disassembled view of an embodiment of an electronic device.

FIG. 2 is similar to FIG. 1, but viewed from another aspect.

FIG. 3 is an enlarged view of part III of the electronic device of FIG. 1.

FIG. 4 is an enlarged view of part IV of the electronic device of FIG. 2.

FIG. 5 is a partially assembled view of part III of the electronic device of FIG. 1.

FIG. 6 is a partially assembled view of part IV of the electronic device of FIG. 2.

### DETAILED DESCRIPTION

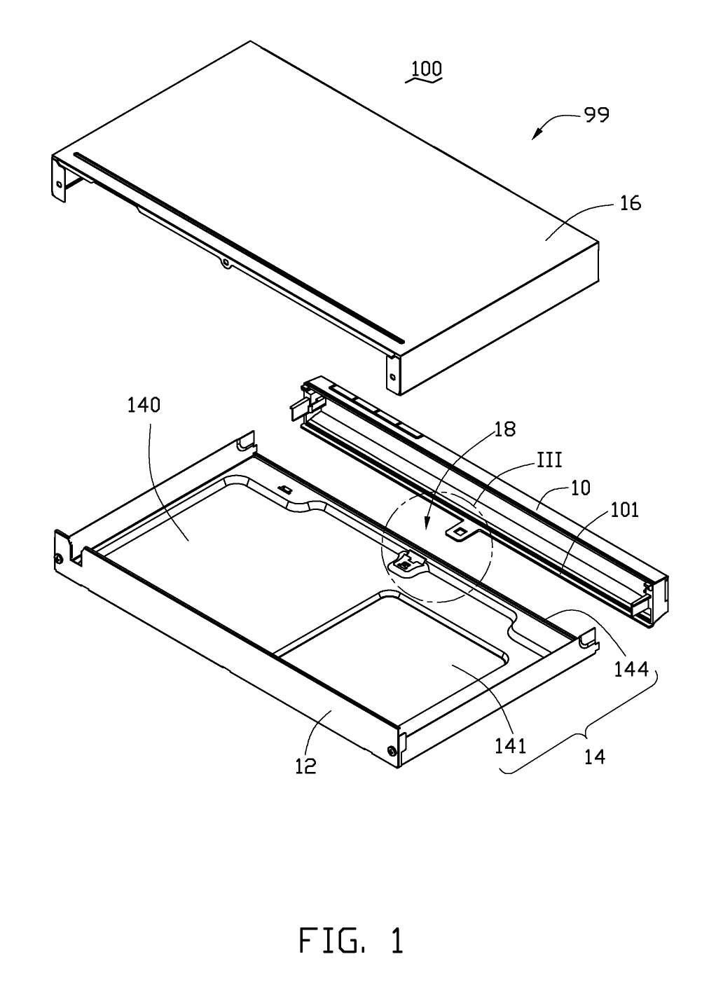

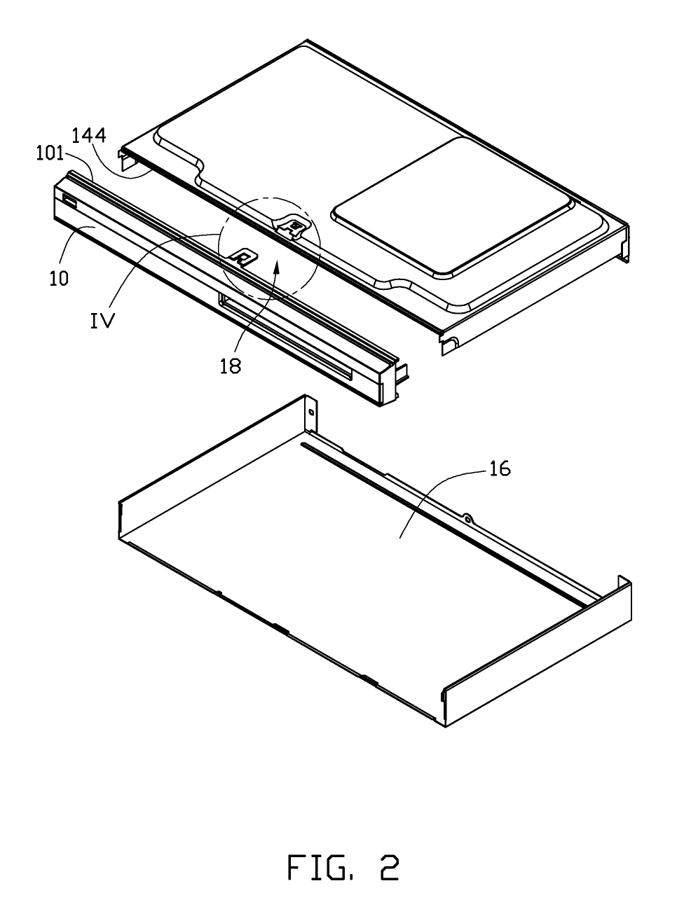

Referring to FIGS. 1 and 2, an electronic device 100 includes a housing 99 and a plurality of components (not shown) received in the housing 99. The housing 99 includes a front panel 10, a back panel 12, a lower cover 14, an upper cover 16, and a fixing mechanism 18. The front panel 10 and the back panel 12 are secured to opposite sides of the lower cover 14. The upper cover 16 covers the lower cover 14 and cooperates with the front panel 10 and the back panel 12 to form a closed space (not labeled) for receiving components of the electronic device 100. The fixing mechanism 18 is used to fix the front panel 10 to the lower cover 14. In the embodiment, the electronic device 100 is a DVD player.

The front panel 10 includes a first rim 101 extending lengthwise along the front panel 10. The back panel 12 is parallel to the front panel 10. The lower cover 14 includes a bottom plate 141 and an edge 144 protruding from a side of the bottom plate 141. The bottom plate 141 includes a first surface 140 facing the upper cover 16 and a second surface 142 at the back of the first surface 140. The edge 144 perpendicularly extends from a rim of the bottom plate 141 lengthwise along the front panel 10 and is parallel to the first rim 101. When the upper cover 16 covers the lower cover 14, the edge 144 connects with the first rim 101.

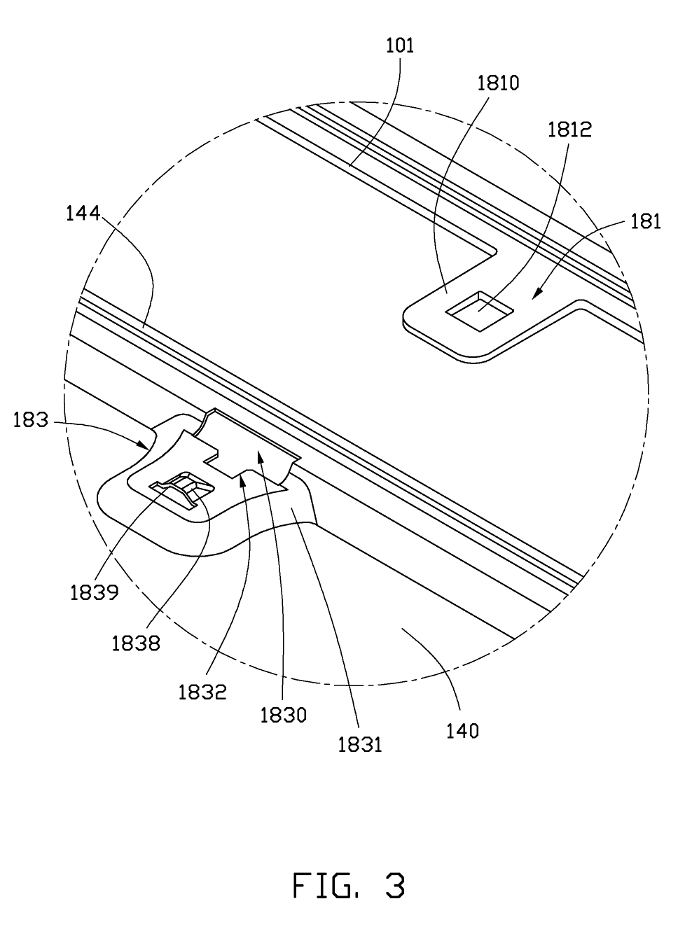

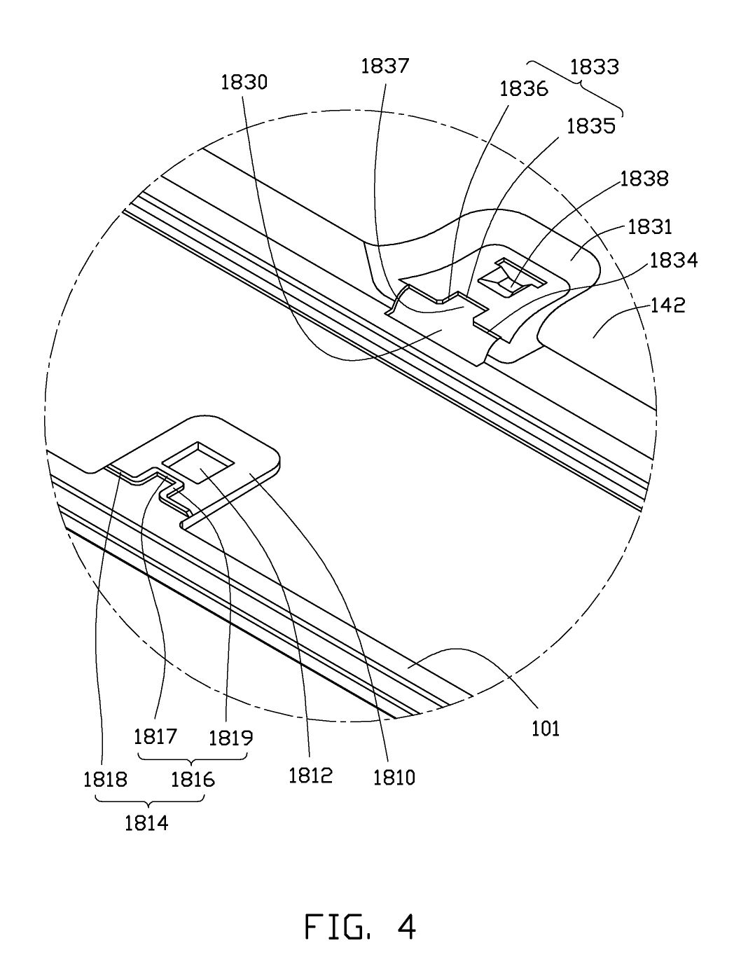

Referring to FIGS. 3 and 4, the fixing mechanism 18 includes a fixing portion 181 and a positioning portion 183 engaging with the fixing portion 181. The fixing portion 181 is positioned on the front cover 10. The positioning portion 183 is positioned on the lower cover 14 for engaging with the fixing portion 181 to secure the front cover 10 to the lower cover 14.

The fixing portion 181 includes a fixing arm 1810 and a resisting portion 1814 formed on the fixing arm 1810. The fixing arm 1810 is substantially a narrow strip, and extends from the first rim 101 toward the lower cover 14. The fixing arm 1810 is made of elastic material and defines a latching hole 1812 spaced away from the resisting portion 1814. The latching hole 1812 is positioned on the middle portion of the fixing arm 1810.

The resisting portion 1814 is positioned on a surface of the fixing arm 1810 opposite to the upper cover 16 and in overall shape resembles a digital square wave. The resisting portion 1814 is positioned between the latching hole 1812 and the first rim 101. The resisting portion 1814 includes a first limiting portion 1816 and two second limiting portions 1818. The first limiting portion 1816 is substantially U-shaped, and connects the two second limiting portions 1818.

The first limiting portion 1816 includes a first rib 1817 parallel to the first rim 101 and two second ribs 1819. The two second ribs 1819 perpendicularly extend in same direction from opposite ends of the first rib 1817. The two second limiting portions 1818 perpendicularly extend from ends of the second ribs 1819 opposite to the first rib 1817.

The positioning portion 183 protrudes out of the first surface 140 of the bottom plate 141 and connects with the edge 144. The positioning portion 183 includes a convex stage 1831 protruding from the first surface 140, a preventing portion 1832, and a protrusion 1838. The preventing portion 1832 and the protrusion 1838 are positioned on the convex stage 1831. In the embodiment, when viewed from the second surface 142 of the bottom plate 141, the convex stage 1831 is recessed in the second surface 142 of the bottom plate 141; when viewed from the first surface 140 of the bottom plate 141, the convex stage 1831 protrudes from the first surface 140 of the bottom plate 141.

The positioning portion 183 defines an inserting hole 1830 at the boundary of the edge 144 and the convex stage 1831. The distance between an edge of the inserting hole 1830 away from the convex stage 1831 and a surface of the convex stage 1831 opposite to and parallel with the first surface 140 (namely, the vertical width of the inserting hole 1830) is slightly larger than the thickness of the fixing arm 1810 so as to allow insertion of the fixing arm 1810. The height of the convex stage 1831 in a direction perpendicular to the first surface 140 is less than the height of the edge 144 relative to the first surface 140.

The preventing portion 1832 is positioned between the inserting hole 1830 and the protrusion 1838. The preventing portion 1832 has the same shape as the resisting portion 1814. The preventing portion 1832 includes a first stopping portion 1833 and two second stopping portions 1834.

The first stopping portion 1833 connects between the two second stopping portions 1834. In the embodiment, the first stopping portion 1833 is a substantially U-shaped recess 1837 defined on the convex stage 1831 and communicating with the inserting hole 1830. The first stopping portion 1833 includes a first stopping wall 1835 parallel to the edge 144 and two second stopping walls 1836. The two second stopping walls 1836 perpendicularly extend from opposite ends of the first stopping wall 1835 in same direction.

The two second stopping portions 1834 perpendicularly extend from an end of the second stopping wall 1836 opposite to the first stopping wall 1835.

The protrusion 1838 further protrudes out of an end of the convex stage 1831 away from the first surface 140 and corresponds to the latching hole 1812. The size of the protrusion 1838 is slightly smaller than the size of the latching hole 1812 to allow the protrusion 1838 to be received in the latching hole 1812. An end of the protrusion 1838 away from the edge 144 defines a cutout 1839. An edge of the cutout 1839 abuts an edge of the latching hole 1812 to prevent the fixing portion 181 from disengaging with the protrusion 1838 when the protrusion 1838 is received in the fixing portion 181.

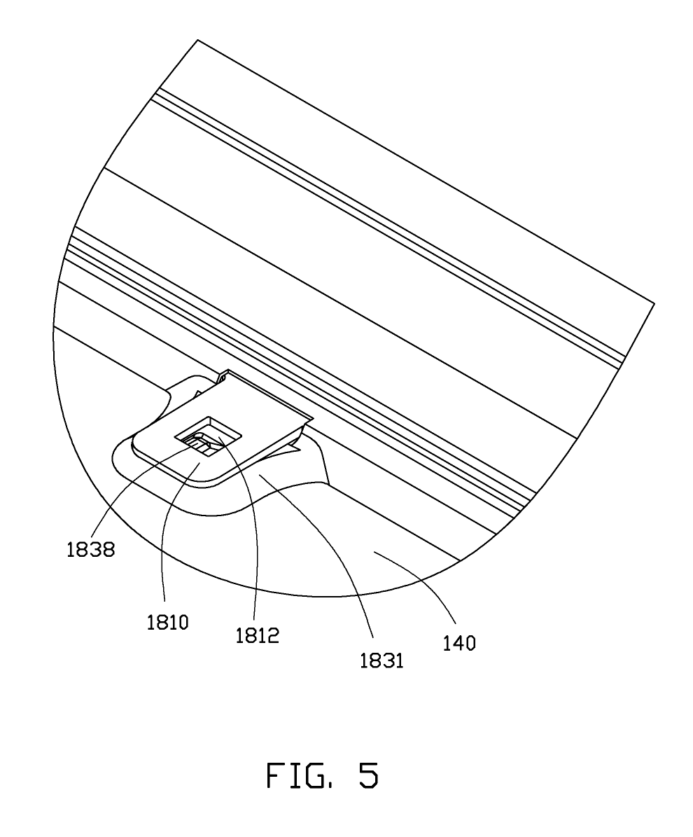

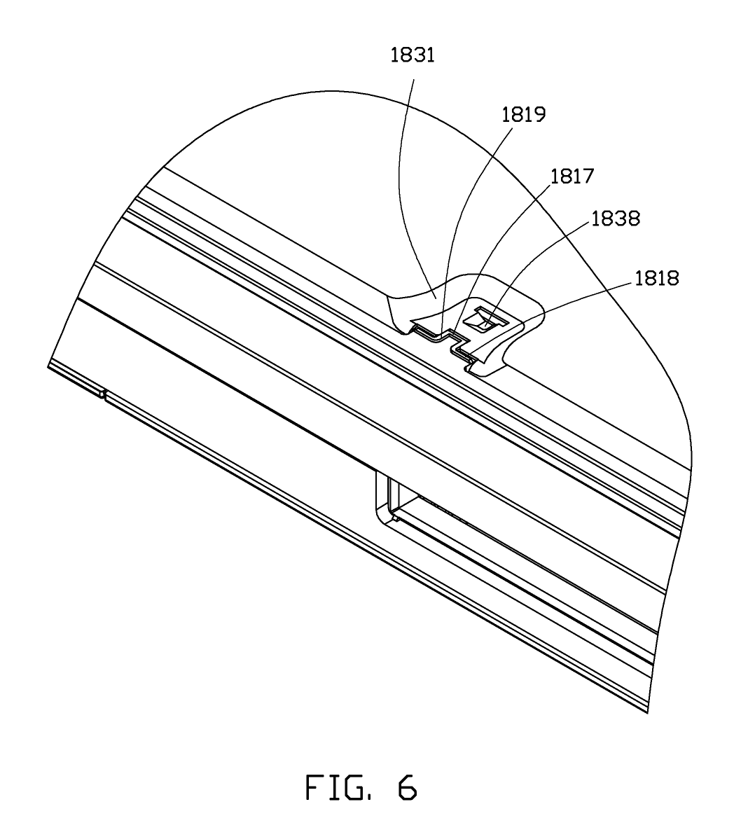

Referring to FIGS. 5 and 6, to secure the front panel 10 to the lower cover 14, firstly, the fixing arm 1810 is horizontally inserted into the inserting hole 1830, and is elastically deformed for allowing the protrusion 1838 to be received in and latched to the latching hole 1812, with an edge of the latching hole 1812 opposite the first rim 101 abutting the cutout 1839, so as to secure the fixing arm 1810 to the protrusion 1838. At the same time, the first rib 1817 and the two second ribs 1819 resist the first stopping wall 1835 and the second stopping wall 1836 respectively. The two second limiting portions 1818 resist the two second stopping portions respectively 1834.

After assembly, the fixing arm 1810 is latched to the protrusion 1838, and an end of the latching hole 1812 opposite to the first rim 101 abuts the cutout 1839, thus, the front panel 10 is prevented from disengaging with the lower cover 14 in a first direction perpendicular to the edge 144. The first rib 1817 resists the first stopping wall 1835, and the two second limiting portions 1818 resist the two second stopping portions 1834 respectively, thus, the front panel 10 is prevented from moving in a second direction which is the reverse of the first direction. Furthermore, the two second ribs 1819 resist the second stopping wall 1836 for preventing the front panel 10 from disengaging with the lower cover 14 in a third and fourth directions perpendicular to the first direction and parallel to the edge 144. Finally, the fixing arm 1810 is limited in the inserting hole 1830 and resisted between the edge 144 and the convex stage 1831, thus, the front panel 10 is prevented from disengaging with the lower cover 14 in a fifth and sixth directions perpendicular to the first and second directions. As a result, the front panel 10 is stably and strongly secured to the lower cover 14.

In disassembly, the front panel 10 is raised relative to the lower cover 14 for allowing the protrusion 1838 to disengage from the inserting hole 1830; then, the front panel 10 is pulled away relative to the lower cover 14 and disengages from the lower cover 14 without the use of a tool.

The fixing mechanism 18 is capable of fixing the front panel 10 to the lower cover 14 securely and rigidly, and allows disassembly and assembly of the front panel 10 to/from the lower cover 14 without any tool, such that the assembly and disassembly process can be quickly and conveniently implemented. The number and the position of the fixing mechanism 18 may be changed according to need. The shape of the resisting portion 1814 can be changed according to need, for example, a block or other protruding structure can be used.

Although information and the advantages of the present embodiments have been set forth in the foregoing description, together with details of the structures and functions of the present embodiments, the disclosure is illustrative only; changes may be made in detail, especially in the matters of shape, size, and arrangement of parts within the principles of the present embodiments to the full extent indicated by the broad general meaning of the terms in which the appended claims are expressed.

What is claimed is:

1. A housing of an electronic device comprising:
a lower cover;
a front panel secured to the lower cover; and
a fixing mechanism arranged between the lower cover and the front panel for securing the front panel to the lower cover, the fixing mechanism comprising:
a fixing arm positioned on the front panel and defining a latching hole; and
a protrusion protruding from the lower cover;
wherein the protrusion is capable of being latched in the latching hole for preventing the front panel from disengaging with the lower cover in a first direction parallel to the fixing arm.

2. The housing as claimed in claim 1, wherein the lower cover comprises a bottom plate, the fixing mechanism comprise a convex stage protruding from the bottom plate, the protrusion further protrudes from an end of the convex stage away from the bottom plate.

3. The housing as claimed in claim 2, wherein an end of the protrusion defines a cutout, an edge of the cutout abuts an edge of the latching hole to prevent the fixing arm from disengaging with the protrusion portion in the first direction.

4. The housing as claimed in claim 2, wherein the fixing mechanism comprises a resisting portion positioned on the fixing arm and a preventing portion positioned on the convex stage, the resisting portion is capable of abutting the preventing portion to prevent the front panel from disengaging with the lower cover in a second direction reverse to the first direction.

5. The housing as claimed in claim 4, wherein the lower cover comprises a sidewall extended from a rim of the bottom cover and connected with the convex stage, the preventing portion is positioned between the sidewall and the protrusion.

6. The housing as claimed in claim 5, wherein the preventing portion comprises a first stopping portion, the first stopping portion comprises a first stopping wall parallel to the sidewall, the resisting portion comprises a first limiting portion, the first limiting portion comprises a first rib, the first rib is capable of resisting the first stopping portion for preventing the front panel from disengaging with the lower cover in the first direction perpendicular to the sidewall.

7. The housing as claimed in claim 6, wherein the preventing portion further comprises two second stopping portions connecting opposite ends of the first stopping portion, the resisting portion comprises two second limiting portions connecting opposite ends of the first limiting portion; the two limiting portions are capable of resisting the corresponding second stopping portion for preventing the front panel from disengaging with the lower cover in the first direction perpendicular to the sidewall.

8. The housing as claimed in claim 7, wherein the resisting portion is further capable of abutting the preventing portion for preventing the front panel from disengaging with the lower cover in a third direction and a forth direction opposite to the third direction and perpendicular to the first direction.

9. The housing as claimed in claim 8, wherein the first stopping portion comprises two second stopping walls perpendicularly connected to opposite ends of the first stopping wall, the resisting portion comprises two second ribs perpendicularly connected to opposite ends of the first ribs, the two second ribs are capable of resisting the corresponding second stopping portion for preventing the front panel from disengaging with the lower cover in the second direction.

10. The housing as claimed in claim 2, wherein the fixing mechanism defines an inserting hole, the fixing arm is capable of limiting in the inserting hole for preventing the front panel from disengaging with the lower cover in a fifth direction and a sixth direction opposite to the fifth direction and perpendicular to the first direction.

11. The housing as claimed in claim 10, wherein the distance between an edge of the inserting hole away from the convex stage and a surface of the convex stage opposite to and parallel with the bottom plate is slightly larger than the thickness of the fixing arm for allowing insertion of the fixing arm and preventing the front panel from disengaging with the lower cover in the third direction perpendicular to the bottom plate.

12. A fixing mechanism for securing a front panel to a lower cover of a housing of an electronic device, the fixing mechanism comprising:
a fixing arm positioned on the front panel and defining a latching hole; and
a protrusion protruded from the lower cover;
wherein the protrusion is capable of latching in the latching hole for latching the fixing arm to the protrusion and preventing the front panel from disengaging with the lower cover in a first direction parallel to the fixing arm.

13. The fixing mechanism as claimed in claim 12, wherein the lower cover comprises a bottom plate, the fixing mechanism comprise a convex stage protruding from the bottom plate, the protrusion further protrudes from an end of the convex stage away from the bottom plate; an end of the protrusion defines a cutout, an edge of the cutout abuts an edge of the latching hole to prevent the fixing arm from disengaging with the protrusion portion in the first direction.

14. The fixing mechanism as claimed in claim 13, wherein the fixing mechanism comprises a resisting portion positioned on the fixing arm and a preventing portion positioned on the convex stage, the resisting portion is capable of abutting the preventing portion to prevent the front panel from disengaging with the lower cover in a second direction reverse to the first direction.

15. The fixing mechanism as claimed in claim 14, wherein the lower cover comprises a sidewall extended from a rim of the bottom cover and connected with the convex stage, the preventing portion is positioned between the sidewall and the protrusion; the preventing portion comprises a first stopping portion, the first stopping portion comprises a first stopping wall parallel to the sidewall, the resisting portion comprises a first limiting portion, the first limiting portion comprises a first rib, the first rib is capable of resisting the first stopping portion for preventing the front panel from disengaging with the lower cover in the first direction perpendicular to the sidewall.

16. The fixing mechanism as claimed in claim 15, wherein the preventing portion further comprises two second stopping portions connecting opposite ends of the first stopping portion, the resisting portion comprises two second limiting portions connecting opposite ends of the first limiting portion; the two limiting portions are capable of resisting the corresponding second stopping portion for preventing the front panel from disengaging with the lower cover in the first direction perpendicular to the sidewall.

17. The fixing mechanism as claimed in claim 16, wherein the resisting portion is further capable of abutting the preventing portion for preventing the front panel from disengaging with the lower cover in a third direction and a forth direction reverse to the third direction and perpendicular to the first direction.

18. The fixing mechanism as claimed in claim 17, wherein the first stopping portion comprises two second stopping walls perpendicularly connected to opposite ends of the first stopping wall, the resisting portion comprises two second ribs perpendicularly connected to opposite ends of the first ribs, the two second ribs are capable of resisting the corresponding second stopping portion for preventing the front panel from disengaging with the lower cover in the second direction.

19. The fixing mechanism as claimed in claim 13, wherein the fixing mechanism defines an inserting hole, the fixing arm is capable of limiting in the inserting hole for preventing the front panel from disengaging with the lower cover in a fifth direction and a sixth direction opposite to the fifth direction and perpendicular to the first direction.

20. The fixing mechanism as claimed in claim 19, wherein the distance between an edge of the inserting hole away from the convex stage and a surface of the convex stage opposite to and parallel with the bottom plate is slightly larger than the thickness of the fixing arm for allowing insertion of the fixing arm and preventing the front panel from disengaging with the lower cover in the third direction perpendicular to the bottom plate.
